(19) United States
(12) Patent Application Publication
(10) Pub. No.: US 2008/0212268 A1
(43) Pub. Date: Sep. 4, 2008

(54) Housing System for Electronic Devices

(75) Inventor: Christian Janisch, Burglengenfeld (DE)

Correspondence Address: LERNER GREENBERG STEMER LLP, P O BOX 2480, HOLLYWOOD, FL, 33022-2480, US

(73) Assignee: VDO AUTOMOTIVE AG, Regensburg (DE)

(21) Appl. No.: 12/064,101

(22) PCT Filed: Jun. 22, 2006
(86) PCT No.: PCT/EP2006/063456

§ 371 Date: Feb. 25, 2008

(30) Foreign Application Priority Data
Aug. 16, 2005 (DE) 10 2005 038 687.3

(51) Int. Cl. H05K 5/00

(52) U.S. Cl. 361/679

(57) ABSTRACT

A housing system for electronic devices, especially for the automobile sector has a top part and a bottom part. A pressure compensation film is fixed to the bottom part of the housing as a top part of the housing. Advantageously, the housing system is flexible, can be individually and thus variably adjusted to the space required, and encompasses a sealing system that is integrated in a pressure compensation element. The housing is suitable particularly for applications in the automobile sector.

The invention relates to a housing system for electronic devices, in particular for the automobile sector, comprising a top part and a bottom part.

Electronic housings fulfill different functions. On the one hand they are used to hold a very wide range of objects, such as printed circuit boards, coils, capacitors etc., to protect them from external influences, and on the other hand they allow the securest possible positioning of such conventional or integrated components.

In the automobile sector the requirements relating to electronic housings are a function of the respective positioning of the housing. If the electronic device is mounted on the engine block or directly in the transmission system, the housing must meet different demands from those it must meet when incorporated in the passenger space. Electronic devices arranged in the region of the engine block are subject to high levels of loading in respect of temperature stability, vibration and impact damping and sealing against water splashes, oil and saline spray fog. Certain minimum requirements are therefore frequently specified for sealing, so that the components in the housing cannot be damaged by external influences. The devices also have to withstand the temperatures that act on them over quite long periods of time without becoming defective. Further requirements for electronic devices consist of them being able to be immersed in icy water without becoming defective and/or remaining operational in a jet of hot water/steam. Electronic housings also have a protective function against dust, stones, oils, alkalis, acids and cleaning agents.

The basic design for an electronic housing known to date from the prior art consists of a housing base and a cover, which are designed to a greater or lesser degree as trough-shaped, in order to hold integrated and/or conventional components. The housing parts are made of different materials, for example steel and aluminum sheet or injection-molded plastic parts and are used in combination with each other. There are different options for sealing the electronic housing. The seal can be previously injected onto the housing base or cover or can be manufactured as a molding variant in the final assembly. It is also possible to use injected or punched insertable seals.

The connection of the housing parts is also a function of the requirements. The housing parts can for example be screwed, riveted, clipped, latched and/or locked to each other. The temperature fluctuations in the environment, which are between −40° C. to 170° C. in the engine space, and the inherent heat of the electronic elements mean that a low or high pressure results in the sealed housings. To compensate for these pressure fluctuations, pressure compensation elements having a membrane which is virtually water-impermeable and vapor-permeable in both directions, are integrated in the housing wall, so that the sealing system and the housing components are not damaged. The vapor permeability required in the pressure compensation element is defined by the respectively required air throughput required per unit of time. It is however a disadvantage here that the degree of sealing of the electronic device is a function among other things of this vapor permeability of the pressure compensation element.

On this basis the object of the present invention is to create a housing system with at least one pressure compensation element, which is easy to mount and at the same time provides a reliable sealing system.

This object is achieved by a housing system for electronic devices with the features of claim 1. Advantageous embodiments and developments, which can be used individually or in combination with each other, are set out in the dependent claims.

The inventive housing system is characterized in that a pressure compensation film is fixed to the bottom part of the housing as the top part of the housing. The elastic film is attached by adhesive to the edge of the housing base in a sealed manner and changes shape as the pressure inside the housing changes. This change in shape changes the internal volume of the housing and adjusts the pressure inside the housing to the external pressure. The volume change brings about a differential pressure compensation.

The expansion of the film can be influenced by way of the film surface, the elasticity of the film material and the surface configuration. A larger film surface, which is also extremely flexible, allows a larger compensation volume for the pressure compensation than with a smaller, less flexible film surface. It is also possible to achieve an increase in the possible compensation volume with a more creative shape, for example by cupping an annular bellows membrane into the film surface. Another option is to emboss the surface, as for example with decorative surfaces, maintaining the film thickness.

It is particularly advantageous if the pressure compensation film is made from a temperature-stable material, since the inventive housing system can then also be incorporated in the region of the motor where extreme temperatures are reached.

It is also advantageous if the pressure compensation film has retaining tabs to enhance the retention forces of the adhesion, thereby preventing the detaching of the film due to the tensile force resulting on the film as a result of low or high pressure. These film tabs allow labeling and the tabs can be used as plates for part identification.

It is also preferable to arrange a closed ring of adhesive surface round the edge of the pressure compensation film, as this makes it easy to assemble the film and also provides a reliable sealing system between the bottom part of the housing and the pressure compensation film, which is also economical, as no additional components are required for the seal.

The inventive housing advantageously allows additional assembly of a protective cover, which is fixed on the bottom part of the housing above the pressure compensation film. This protects the film against mechanical influences such as stones for example. If necessary, this protective cover can be configured in such a manner that the adhesive or sealing surface of the film is also pressed onto the sealing system from outside, generally enhancing the quality of the seal and minimizing the risk of possible leaks.

To prevent tearing or premature aging of the film in the event of excessive strain as a result of over-expansion, limiter elements can advantageously be attached both to the bottom part of the housing and to the protective cover to limit the movement of the film (e.g. studs, ribs, domes).

It is also possible to use a vapor-permeable pressure compensation membrane for large compensation volumes, which alone is not adequate in respect of the required seal due to the necessary vapor permeability for the air throughput.

The present invention first advantageously creates a flexible housing system that can be adjusted individually and therefore variably to the space available with a sealing system integrated in a pressure compensation element. It is particularly suitable for applications in the automobile sector.

Further advantages and refinements of the invention are described in more detail below with reference to an exemplary embodiment and with reference to the schematic drawings, in which:

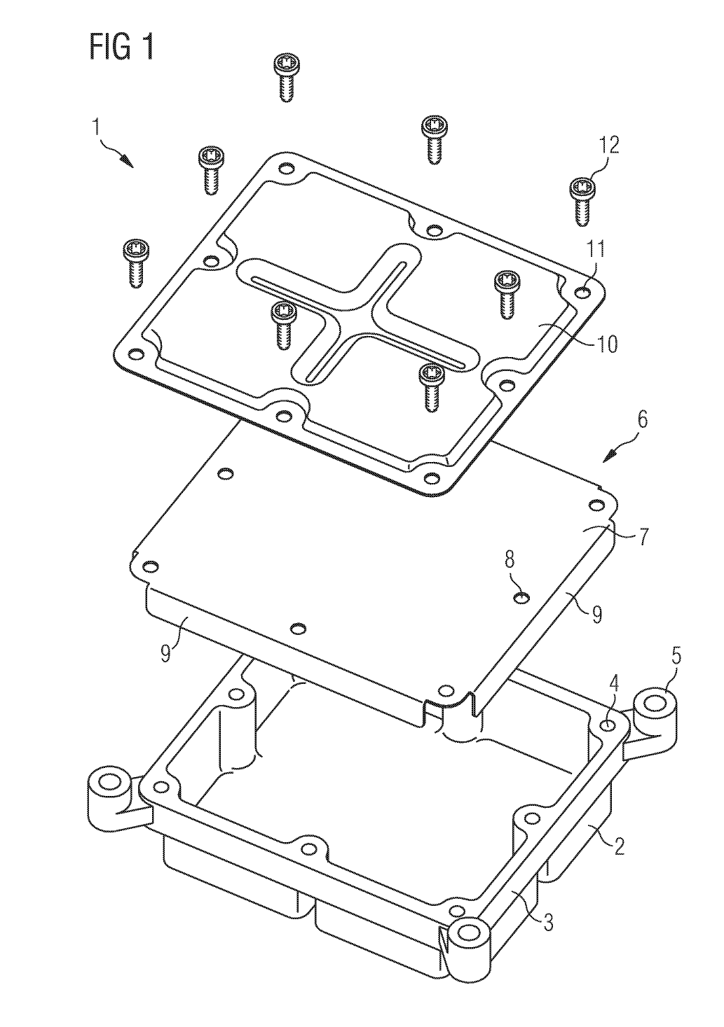

FIG. 1 shows an exploded top view of an inventive housing system;

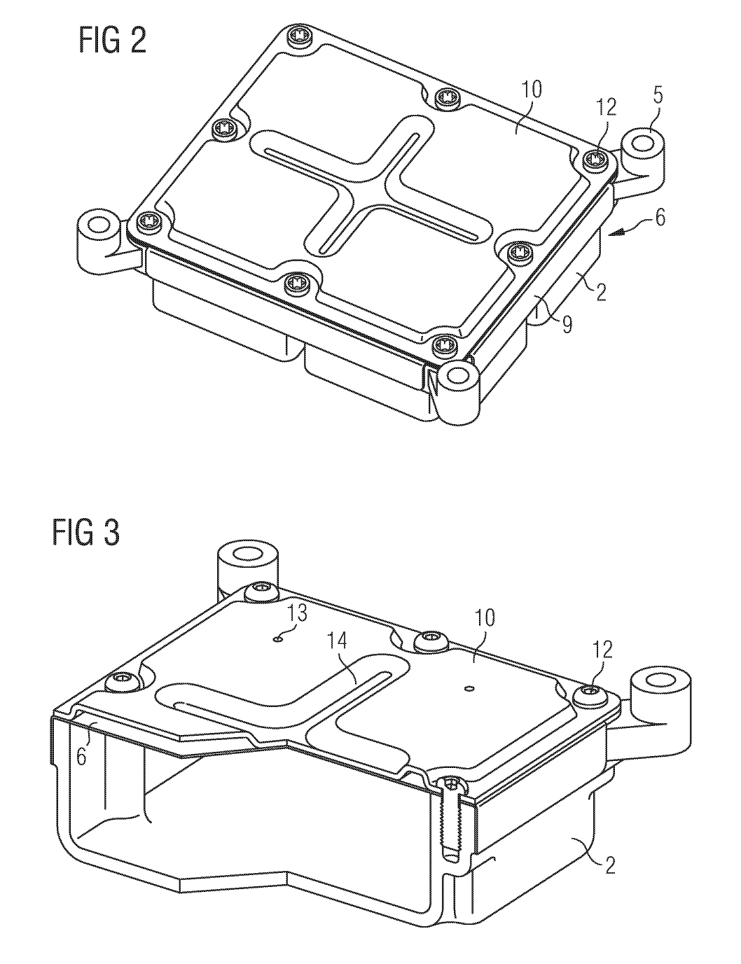

FIG. 2 shows a top view of the inventive housing system;

FIG. 3 shows a perspective view of the housing system shown in FIGS. 1 and 2 with pressure compensation film;

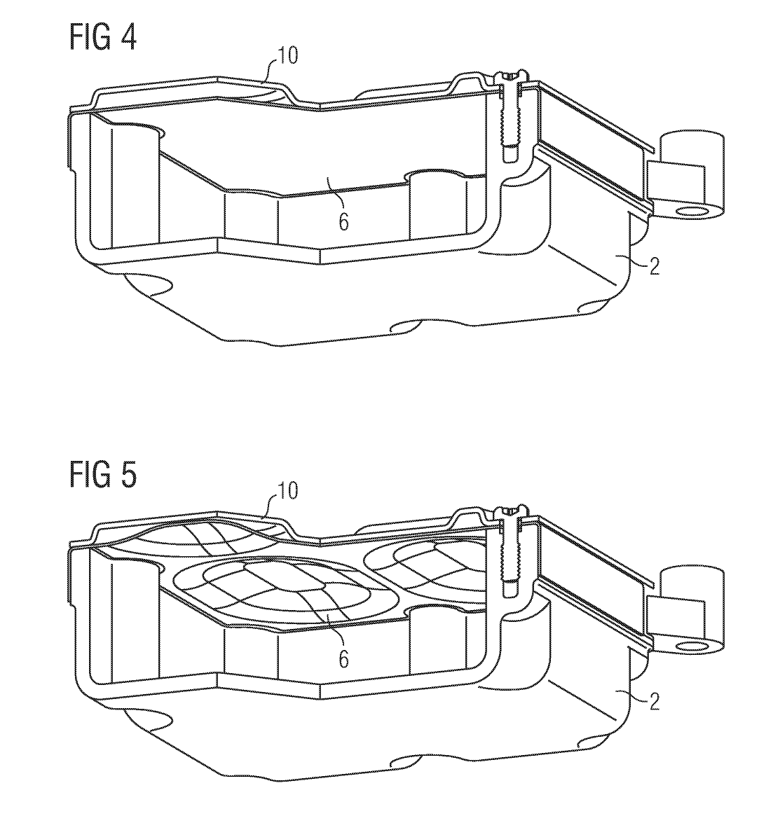

FIG. 4 shows a perspective view of the inventive housing system with pressure compensation film at normal pressure;

FIG. 5 shows a perspective view of the inventive housing system with pressure compensation film at high pressure;

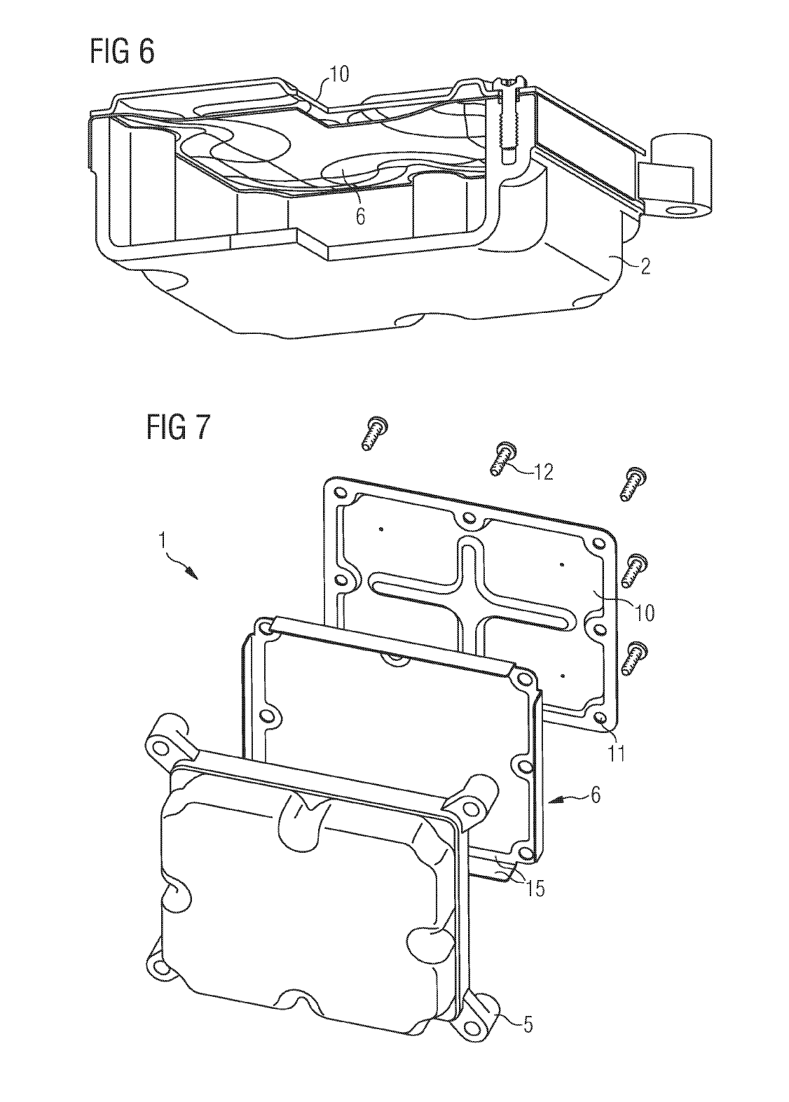

FIG. 6 shows a perspective view of the inventive housing system with pressure compensation film at low pressure; and

FIG. 7 shows an exploded perspective view of the inventive housing system with pressure compensation film from below.

FIG. 1 shows an exploded view of the structure of an inventive housing system 1. The housing system 1 shown in FIG. 1 comprises a trough-shaped housing bottom part 2 with a preferably rectangular base surface, with cutouts 4 arranged on its housing edge 3, preferably at regular intervals. Preferably cylindrical screw eyelets 5 are arranged respectively in the corners of the trough-shaped housing bottom part 2. A pressure compensation film 6 is fixed to the edge 3 of the housing bottom part 2 above the housing bottom part 2, having a base surface 7, which corresponds to the base surface of the trough-shaped housing bottom part 2. This pressure compensation film 6 is preferably temperature-stable and elastic. Holes 8 are arranged in the pressure compensation film 6 in the same positions as the cutouts 4 in the housing bottom part 2. Retaining tabs 9 are arranged respectively on the longitudinal and transverse sides of the pressure compensation film 6 and these serve as additional adhesive surfaces. These retaining tabs 9 are interrupted respectively at the corners of the pressure compensation film 6. A protective cover 10 can be arranged above the pressure compensation film 6, having through holes 11 in the same positions as the cutouts 4 in the housing bottom part 2 and the holes 8 in the pressure compensation film 6. The protective cover 10 can be fixed to the housing bottom part 2 by way of securing means 12, such as screws, which are inserted through the through holes 11 in the protective cover 10 and the holes 8 in the pressure compensation film 6 into the cutouts 4 in the housing bottom part 2.

FIG. 2 shows a schematic diagram of the inventive housing system 1 in the screwed-in state. In the screwed-in state the retaining tabs 9 of the pressure compensation film 6 are fixed, preferably by adhesive, to the outer housing edge 3 of the housing bottom part 2.

FIG. 3 shows a perspective view of the inventive housing system 1 with a pressure compensation film 6 secured additionally on the outside and used as a label. The protective cover 10 has a cupped region, which serves as a movement limiter element 14. The protective cover 10 also has pressure compensation holes 13.

FIGS. 4 to 6 show perspective views of the inventive housing system 1 with the pressure compensation film 6 at normal pressure (FIG. 4), high pressure (FIG. 5) and low pressure (FIG. 6).

FIG. 7 shows an exploded view of the inventive housing system from below, with a closed annular adhesive surface 15 applied from below round the pressure compensation film 6, representing the sealing surface in the adhered state.

The inventive housing system has the following advantages:

Ideally the pressure compensation film 6 replaces the housing cover and screws, thereby reducing production and assembly costs. The sealing adhesive of the film 6 also means there is no need for cost-intensive sealing or the technically complex and qualitatively demanding casting process. Application of the film 6 by adhesion represents a reliable and easy method. A sealed system is used, which compensates for pressure changes by volume changes. Because the film surface seal is adhered on the edge surfaces it provides a simpler and more compact sealing system than the not particularly space-saving variants with seals that are inserted or sprayed on or cast from the prior art. Compared with casting, when a pressure compensation film 6 is used, it is possible to repair the device other than during manufacture, for example in a vehicle workshop, by opening and resealing with new film. Adhesion allows greater tolerance and therefore a lower level of dimensional accuracy of the housing components. This sealing system with adhesion on the edge surfaces is generally easier to use due to its two-dimensionality than three-dimensional sealing or casting methods.

The present invention first advantageously creates a flexible housing system that can be adjusted individually and therefore variably to the space available with a sealing system integrated in a pressure compensation element. It is particularly suitable for applications in the automobile sector.

1-7. (canceled)

8. A housing system for electronic devices, the housing system comprising:
a housing bottom part; and
a pressure compensation film fixed to said housing bottom part and functioning as a housing top part.

9. The housing system according to claim 8, wherein said pressure compensation film is elastic.

10. The housing system according to claim 8, wherein said pressure compensation film is temperature-stable.

11. The housing system according to claim 8, wherein said pressure compensation film has retaining tabs.

12. The housing system according to claim 8, further comprising a closed ring having an adhesive surface disposed around an edge of said pressure compensation film.

13. The housing system according to claim 8, further comprising a protective cover fixed to said housing bottom part by way of said pressure compensation film.

14. The housing system according to claim 8, further comprising limiter elements for stabilizing said pressure compensation film.

15. A housing system for electronic devices for the automobile sector, the housing system comprising:
a housing bottom part; and
a pressure compensation film fixed to said housing bottom part and functioning as a housing top part.
